(19) United States
(12) Patent Application Publication
(10) Pub. No.: US 2007/0154021 A1
(43) Pub. Date: Jul. 5, 2007

(54) Digital feedback to improve the sound reproduction of an electro-dynamic loudspeaker

(76) Inventor: Mikael Bohman, Skogstorp (SE)

Correspondence Address: LYNN E BARBER, P O BOX 16528, FORT WORTH, TX, 76162, US

(21) Appl. No.: 11/641,325

(22) Filed: Dec. 19, 2006

Related U.S. Application Data
(60) Provisional application No. 60/753,003, filed on Dec. 22, 2005.

(51) Int. Cl. H04R 29/00; H03G 3/00

(52) U.S. Cl. 381/59; 381/61

(57) ABSTRACT

The present invention describes a solution based on software together with hardware for digital control of a loudspeaker based on feedback from a current sensor, which replaces the existing analog technology, improves the frequency response and improves the controllability over the distortion. This method solves problems with temperature sensitivity and resonant behavior. It also opens up for new combinations of digital tools to be integrated to the system, such as digital crossover networks, digital pre compensation and digital room correction, this to achieve a better overall sound reproduction. It also solves problems with control systems based on electrical components, which might drift away with temperature and age. It can further on be made more user friendly when used together with a graphical user interface interacting with the hardware and software in real-time.

### CROSS-REFERENCE TO RELATED APPLICATIONS

This is application claims priority from U.S. provisional application Ser. No. 60/753,003 filed Dec. 22, 2005, which is incorporated herein by reference.

### BACKGROUND OF THE INVENTION

1. Field of the Invention

The present invention relates to the use of feedback systems in electro-dynamic applications such as loudspeakers, and an apparatus for carrying out the method.

2. Description of the Related Art

There are many ways to accomplish good bass reproduction in loudspeakers. One is to have large cabinets and large woofers. In practice, methods of accomplishing this often result in problems. The lower limit for a woofer is set by the resonance frequency, which is in relation to the ratio between mass and compliance acting on the membrane. Thus a solution to keep a low resonance frequency is to add more weight by increasing the membrane's mass. One drawback with more mass is the reduced sensitivity i.e. less sound pressure per electric watt.

Seen from the amplifier's point of view, the loudspeaker is an electrical component with its mechanical attributes transformed into electrical magnitudes. The mass corresponds to a capacitance, and the compliance to an inductance that is in parallel with the capacitance. The mechanical damping corresponds to a resistance that is in parallel with both of the above. By adding more inductances, resistances and capacitances, one should be able to change the loudspeaker's mechanical attributes, but there is a catch. The drive unit's voice coil has an impedance that lies serially with the parallel ‘mechanical’ components. This means that one cannot parallel-connect directly to the woofer's mechanical parameters.

Improvements of the bass response for electro-dynamic loudspeakers, based on current feedback, are for example described in U.S. Pat. No. 4,118,600, which describes an analogue apparatus that uses negative resistance and impedance loading. The loudspeaker normally exhibits actual mechanical parameters such as damping, compliance, and mass which normally determine the bass response and lower cut-off frequency of the loudspeaker. The method and apparatus of that invention cause the loudspeaker to exhibit apparent mechanical parameters which differ from the actual mechanical parameters to substantially change the effect of the actual mechanical parameters on the bass response. Thus, the apparatus improves the frequency response of the loudspeaker, but it also reduces nonlinearities in the loudspeaker compliance. Some flaws of the apparatus are that it suffers from frequency response problems such as resonant behavior and high frequency roll off. From a control system point of view, the resonant behavior can be explained as a too small phase-margin for the closed control system. The problem arises from the electrical voice coil inductance. The voice coil inductance also introduces increased nonlinear distortion for high frequencies when using the apparatus of that invention,

Such an apparatus also suffers from a high sensitivity for changes in the voice coil temperature. The frequency response is dependent of the voice coil resistance, and the voice coil resistance is correlated to the voice coil temperature. The voice coil temperature is affected by the electrical power fed to the loudspeaker, thus is dependent on the volume at which the sound is played thereon. Therefore the frequency response of the apparatus is affected by the sound volume.

A similar analogue apparatus which reduces the problems with the high frequency roll off and increased distortion for high frequencies is described in patent SE450613. Briefly, the output signal from the above mentioned apparatus is combined with a high-pass filtered version of the input signal before the power amplifier. Together with an all-pass filter an approximately flat frequency response is achieved.

In the present invention a digital feedback system is used which is based on software together with hardware in contrast to the earlier mentioned analogue apparatuses. The digital approach gives the breakthrough possibility to combine the digital solution for a feedback system with other digital control solutions in the same digital processor which altogether improves the sound reproduction, compared to any analogue system.

The digital approach also renders improvements of the frequency response and higher controllability over the distortion compared to above mentioned analogue apparatuses. It can also be made adaptive to track changes over time in the loudspeaker, for example, to follow and compensate for changes in the voice-coil temperature. Changes in the voice coil temperature are a pitfall in the earlier mentioned analogue apparatuses, since it also changes the overall frequency response. A complex and adapting model over the voice coil impedance is not possible with an analogue circuit, such as, for example, the analogue apparatus shown in U.S. Pat. No. 4,118,600 and in SE450613.

The digital approach also solves problems with control systems based on analogue components that needs to be manually trimmed, and which might drift away with age and the surrounding temperature.

The digital solution further gives the possibility to attach a graphical user interface to interact with the digital feedback system in real time. For example, the user interface can be integrated to the already existing user interface in modern power amplifiers. This opens up for new combinations, since the analogue approach needs to be trimmed to each loudspeaker it is connected to.

A loudspeaker of the electro-dynamic type is a moveable voice-coil in an air gap between the poles of a magnet and connected to a membrane of some sort.

To describe the relation between electrical quantities such as current I and voltage U, mechanical quantities such as velocity v and force F and acoustical quantities such as pressure p and volume flow Q, electrical-mechanical-acoustical analogies can be used. Mechanical force is there treated as electric voltage, velocity as current, mass as inductance, damping as resistance and compliance as capacitance. The relationship between the electrical, mechanical and acoustic side can be represented as an equivalent circuit shown in FIG. 1. In this figure the voice coil shows a resistance R_{E}, and an inductance L_{E} on the electrical side. The speaker element comprises the moving mass M_{MS}+M_{MK}, the damping R_{MU}, and the compliance C_{MU} on the mechanical side. On the acoustical side there will be seen a radiation load R_{AL} and the mass reactance M_{AL}, from the surrounding air. A gyrator is placed between the electrical and mechanical domain with transduction coefficient Blκ (force factor), and a transformer is placed between the mechanical and acoustical domain with transduction coefficient S (surface). A gyrator or dual transformer also called “Inverting transformer” describes an element that exhibits an inverting property. It converts impedances and generators into its inverses.

The operator κ is a versor and only turns, or rotates, the directions in space. More precisely it signifies a 90° rotation in physical space.

More compact equivalent circuits can be drawn if all components in the same domain are replaced by one single impedance. In FIG. 2, all electrical components are assembled to the electrical impedance Z_{E}, all mechanical components are assembled to the mechanical impedance Z_{M}, and all acoustical components are transformed over to the mechanical domain adding the impedance Z_{MA}.

In the present invention, the voice coil inductance L_{E} of the loudspeaker element does not show the same behavior as an ordinary coil since the coil is placed in a magnetic circuit, for example around a soft-iron pole piece. For this reason the resistive part of the voice coil inductance increases towards higher frequencies. The voice coil inductance L_{E} can be modeled as:
Z(jω)=Kωⁿe^{in1/2π}

The parameters K and n for a driver can be obtained from measured voice coil impedance or admittance data. FIG. 3 shows a simulation of the electrical impedance of a loudspeaker in free air. The dotted line shows the behavior if the voice coil was an ordinary coil (n=1), and the straight line shows a simulation when n=0.7, which is a much better estimate of a real loudspeaker impedance.

For a graphical representation of some of the prior art, see also FIG. 12.

Other objects and advantages of the invention herein will be more fully apparent from the following disclosure.

### SUMMARY OF THE INVENTION

The invention provides a solution to the problems set forth above, which solution is based on adding effective output impedance that is substantially greater than zero for low frequencies to a power amplifier. Furthermore the effective output impedance might consist of both positive and negative resistance depending on the frequency.

The present invention relates to the findings that the described solution based on software together with hardware for digital control of a loudspeaker based on current feedback from a resistor in serial with a loudspeaker, which replaces the existing analogue technology, improves the frequency response and improves the controllability over the distortion. This method can also reduce the temperature sensitivity with the use of adaptive filters. It also opens up for new combinations of digital tools to be integrated to the system, such as digital crossover networks, digital pre compensation and digital room correction to achieve a better overall sound reproduction. It also solves problems with control systems based on electrical components, which might drift away with temperature and age. It can further on be made more user friendly when used together with a graphical user interface interacting with the hardware and software in real-time.

Other objects and features of the inventions will be more fully apparent from the following disclosure and appended claims.

### BRIEF DESCRIPTION OF THE DRAWINGS

FIG. 1 illustrates the equivalent electrical-mechanical-acoustical circuit of an electrodynamic loudspeaker herein.

FIG. 2 illustrates a compact equivalent circuit of an electrodynamic loudspeaker where the acoustical components are transformed to the mechanical domain herein.

FIG. 3 illustrates a computer simulation of a voice coil impedance for an electrodynamic loudspeaker. The dotted line shows a simulation as if the voice coil would be treated as an ordinary coil. The solid line shows a simulation of an electrodynamic loudspeaker which is a much better estimate of an actual loudspeaker impedance.

FIG. 4 illustrates a block diagram with the basic layout over the digital feedback system herein.

FIG. 5 illustrates the equivalent generator to the feedback system illustrated in FIG. 4.

FIG. 6 illustrates an equivalent circuit where the generator in FIG. 5 is connected to the electrodynamic loudspeaker in FIG. 2.

FIG. 7 illustrates the mechanical equivalent circuit from FIG. 6 when Z_{E} equals G.

FIG. 8 illustrates a block diagram of the extended layout over the digital feedback system herein.

FIG. 9 illustrates the block diagram from FIG. 8 equipped with a digital General Purpose (GP) block.

FIG. 10 illustrates a layout of the physical components of the invention.

FIG. 11 illustrates a simulation of the output impedance of the apparatus. The plots to the left shows the resistance and the reactance as a function of frequency and the plots to the right shows Nyquist plots of the output impedances.

FIG. 12 illustrates a graphical representation of some of the prior art. Search words: Electrodynamic, Voice coil, Loudspeaker, Control, Servo, Current feedback

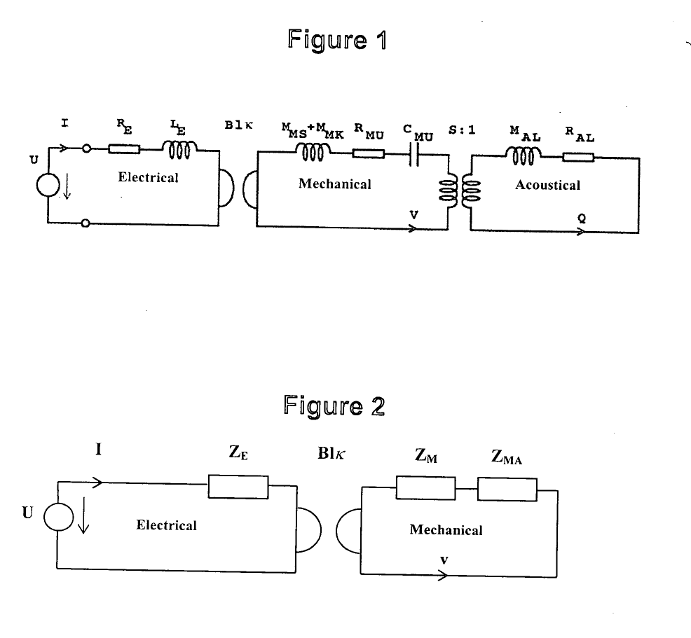

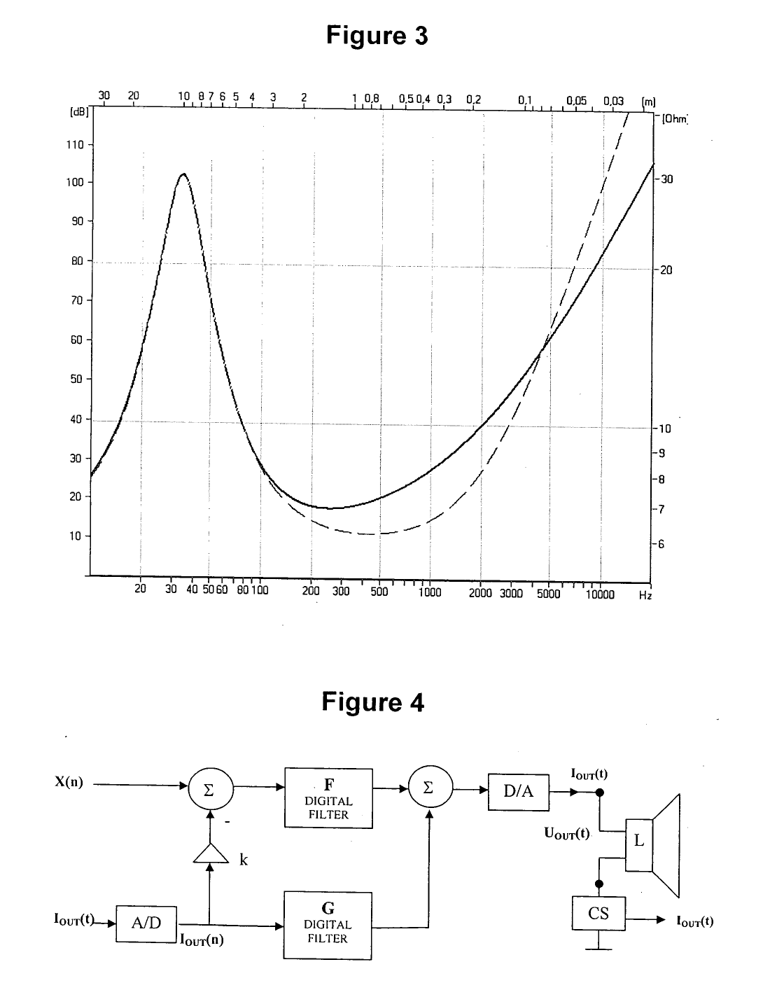

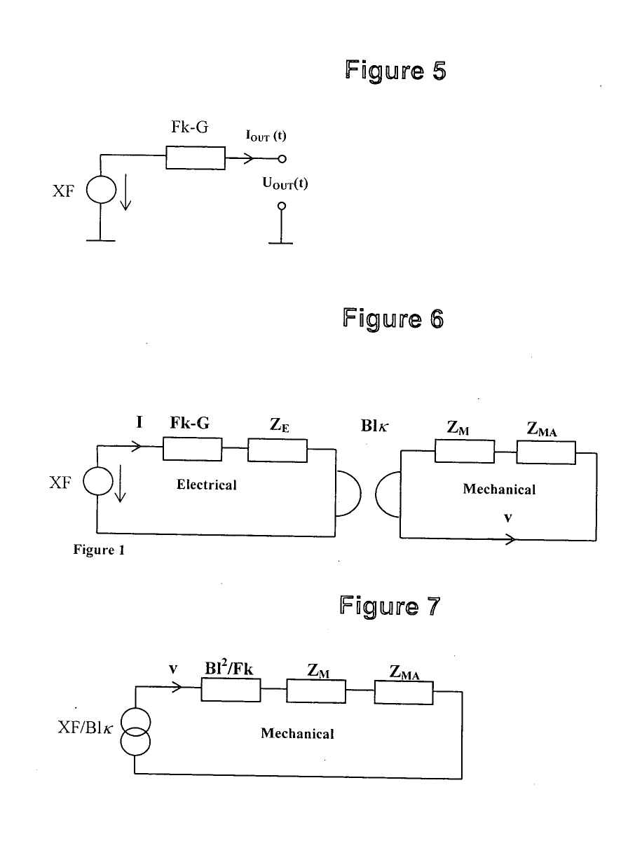

### DETAILED DESCRIPTION OF THE INVENTION AND PREFERRED EMBODIMENTS THEREOF

The invention herein is an apparatus based on software together with hardware for digital control of a loudspeaker based on feedback from a current sensor, which replaces existing analogue technology, improves the frequency response and improves the controllability of distortion. The invention may be combined with digital tools as described herein such as digital crossover networks, digital precompensation and digital room correction to achieve a better overall sound reproduction.

In the invention, a digital control system is placed between the source signal X and the loudspeaker L (FIG. 4). A current sensor CS is placed in serial with the loudspeaker, measuring the output current I_{OUT}, fed to the loudspeaker. For example the current sensor can be made from a current sensing resistor together with a differential amplifier.

The control system is fed with a digital stream of data X(n), for example sampled music. The control system is also fed with the time continuous signal I_{OUT}(t), delivered from the current sensor. The signal I_{OUT}(t) is then analogue to digital converted in the A/D converter, creating the digital stream of data I_{OUT}(n).

The converters need to have a small latency from the input to the output. For example, successive approximation SA converter (hardware) with minimum-phase anti-aliasing filters can be used. The low latency in the A/D converter is important since the control system is based on feedback. Time delays will affect the frequency response of the control system, and reduce the stability margin.

F and G (FIG. 4) are any type of digital implemented filters. Filter G is in the simplest form only a constant, but it can with advantage be a time variant polynomial, i.e. an adaptive filter, and filter F is for example a second order band pass Infinite Impulse Response (IIR) filter. The sum of the output from filters F and G are digital to analogue converted in the low latency D/A converter. A power amplifier is put after the converter to amplify the signal U_{OUT}(t) and supply the need of current to the loudspeaker. The constant k is a scale factor.

The calculations are processed in real-time in some type of digital processor, for example, a digital signal processor (DSP). The processor runs the computations sample by sample to reduce the latency thru the system, or block wise depending on which sample rate that is chosen.

If the time delay in the A/D or D/A converters can be neglected, the closed system can be described as:

$$( X - {I}_{OUT} k ) F + {GI}_{OUT} = {U}_{OUT}$$

$$XF - {I}_{OUT} kF + {I}_{OUT} G = {U}_{OUT} \\ ⇒ {U}_{OUT} = XF - {I}_{OUT} ( Fk - G )$$

$${U}_{OUT} = U - {I}_{OUT} {Z}_{OUT}$$

The output impedance Z_{OUT} and the voltage U can thus be identified as:
Z_{OUT}=Fk−G
U=XF

The control system can thus be reduced to the generator showed in FIG. 5. If the analogy from FIG. 2 is assembled with the control system in FIG. 5 the result is shown in FIG. 6. If filter G (FIG. 4) is equal to Z_{E}, the system can be reduced to the equivalent mechanical circuit illustrated in FIG. 7, where Z_{M} is in series with Bl²/Fk which is the result when transforming the filter F multiplied with the constant k through the gyrator with transduction coefficient Blκ. Thus, the coefficients given to the digital filter F (FIG. 4) will apparently change the mechanical quantities Z_{M} (FIG. 7) of the loudspeaker. If filter F is made as a second order band pass filter, the coefficient in filter F will change the appearance of the moving mass, mechanical resistance and compliance of the loudspeaker.

Since Z_{M} is in series with Bl²/Fk (FIG. 7), nonlinear components in Z_{M} will be decreased in Z_{M}+Bl²/Fk, since F is a linear filter. This will reduce the distortion seen in Z_{MA}, i.e. reducing the distortion in the sound created by the loudspeakers.

A smaller loudspeaker cabinet generally introduces more nonlinear compliance due to the air which is compressed inside the loudspeaker cabinet. The amount of nonlinearity stands in relation to the sound pressure generated in the cabinet

On the other hand a large loudspeaker element with a long maximum excursion often has a large electrical inductance, and which inductive part is significantly dependent on the position of the moving voice coil in the magnetic gap. From that perspective a negative output resistance from the amplifier will increase the distortion from the loudspeaker for some frequencies, and positive output resistance will decrease it.

To reduce the overall output distortion both negative and positive effective output resistance can be applied to the amplifier. Mainly negative output impedance is applied for frequencies where the largest contribution of distortion arise from the nonlinear compliance, and mainly positive output impedance is applied for frequencies where the largest contribution arise from the voice coil in the magnetic gap.

The effective output impedance from the amplifier consists of both a resistive part and a reactive part together. The effective output reactance of the amplifier will be affected by the frequency dependent resistance since the resistance and the reactance relates to each other, and might also change between positive and negative values.

With the digital control system showed above it is possible to reproduce low-frequency distortion reduced bass from small loudspeaker cabinets, which is not possible with system based on linear feed forward control, such as equalizers.

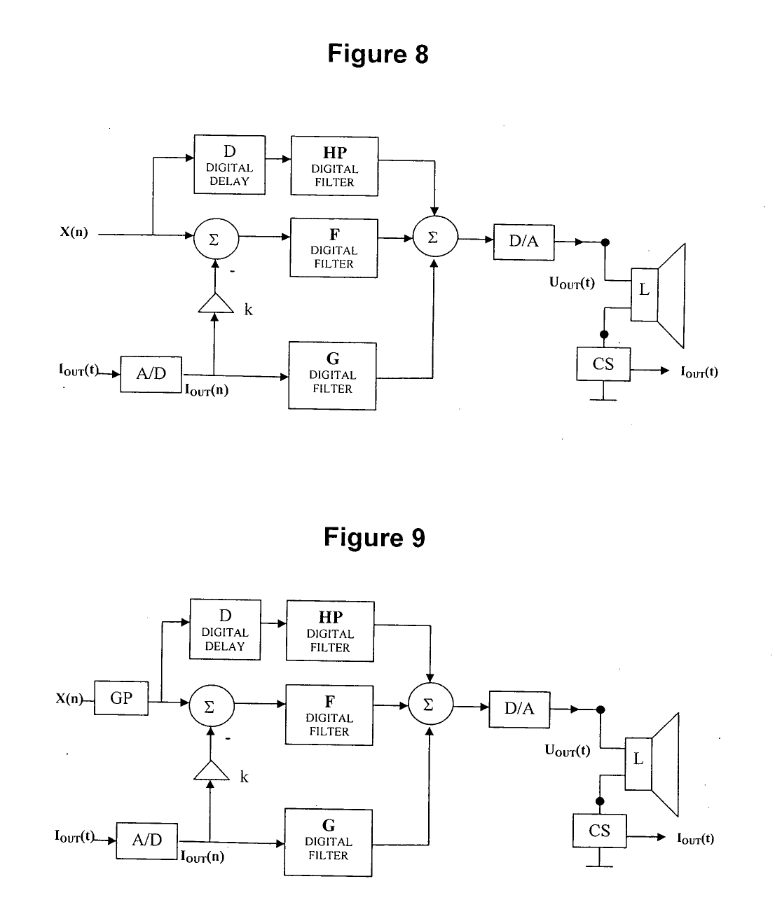

One earlier mentioned problem was the roll of and increased distortion for high frequencies. A method solving those problems is showed in FIG. 8.

Since the system described in FIG. 4 can be said to be working as a low pass (LP) filter on the acoustical output, the idea is to combine the output with a high pass (HP) filter branch, so the output signals from the two filters LP and HP, together sums to unity. To achieve the correct phase for unity between the branched LP and HP filters, a digital delay (D) might be used in series with the high pass filter.

With this approach it is possible to reproduce low-frequency, distortion reduced bass from small loudspeaker cabinets and mid or high frequencies with the same loudspeaker element. It is with this concept possible to build a small two-way loudspeaker with a woofer and a tweeter that alone covers the whole audible frequency range with a flat frequency response (on axis) in the earlier mentioned range, with reduced non linear distortion.

The concept can for example be combined with digital crossover networks, digital equalizers for frequency response correction and/or digital room correction, integrated in the same system, which are shown as a general purpose block GP illustrated in FIG. 9. It was earlier mentioned that the filter G (FIG. 4) must be equal to the electrical impedance Z_{E} to achieve the possibility to directly change mechanical parameters from the control system. Some problem arises since the voice coil resistance is temperature and frequency dependent and the voice coil inductance is frequency dependent and also dependent on the excursion of the voice coil.

To solve some of the problem the filter G (FIG. 4) can be made adaptive. Thus, when the resistance in the voice coil is changing due to temperature change, the filter G should follow and adapt to the change.

The information used for the adaptation can be based on different inputs. For example, a small but well known DC offset can be set in the power amplifier or a constant value can be added to the output from the control system. The second approach demands power amplifiers with a flat frequency response down to DC. Based on an average of the DC-current flow thru the loudspeaker, the DC resistance can be computed and used for adaptation. Another more robust but computationally more complex approach, is to use an observer, observing the U_{OUT} and the I_{OUT}. The observer can then calculate a transfer finction for Z_{E}, which in a restricted form can be used to estimate the filter G.

Since the Signal to Noise Ratio (SNR) for audio system is of great importance, a disturbance in the control system cannot be amplified too heavily. Thus it is not possible to allow filter G to be fully compensated for the whole audible range. Filter G must therefore always be a restricted estimate of Z_{E}, in such a way that the phase margin is hold under control.

Since the earlier mentioned voice coil impedance is not acting as a common coil, the model complexity of an accurate estimate of filter G increases.

From a limited amount of poles and zeroes in the digital filter G, it is possible to create a transfer function that is close enough the estimate of Z_{E} for a bounded frequency range.

Rather than specifying the filter G in terms of functions of the frequency, it can be describe as a rational function of q(−1), there q(−1) is a delay operator, specifying the numerator and denominator coefficients.

One of the most used models is the ARX model structure, commonly described as:
A(q)y(t)=B(q)u(t−nk)+e(t)

where A and B are polynomials, t is time, e is noise and u and y are the input and the output signal to the model. The number nk is the number of delays from input to output.

To find the coefficients to the polynomial A and B, for example, the least square (LS) method or the four-stage instrumental variable (IV) procedure can be used.

To choose the order of the polynomial A and B, loss functions for families of ARX-models can be computed, there a suitable balance between the model order and model error can be chosen.

When the system identification of the voice coil impedance Z_{E} is settled, for example, with the above mentioned ARX-mode or based on analytic expression of the impedance such as show in FIG. 3, a Single Input Single Output (SISO) design tool can be used to optimize the filter G in the digital feedback system. The demands on frequency response, robustness and sensitivity can therein be controlled. Since filter G with advantage can be made adaptive as earlier described, the outcome from the SISO tool can be used as an initial guess for the adaptation. In the SISO tool the location for poles and zeros for filter G can be identified and exported to the earlier mentioned software which runs on the digital signal processor.

The nonlinear distortion created in the voice coil inductance L_{E} manly arises from the fact that when the coil is moving, the amount of soft iron inside the coil is changing. This mainly introduces even overtones to the signal.

By decreasing the influence of filter G, i.e., decreasing the negative output impedance, it is possible to control the type of distortion which is created. Increasing the negative output impedance generally increase the first harmonic, and decrease the second harmonic. This approach can therefore be used to color the distortion of the sound.

The features of the present invention will be more clearly understood by reference to the following examples, which are not to be construed as limiting the invention.

### Example 1

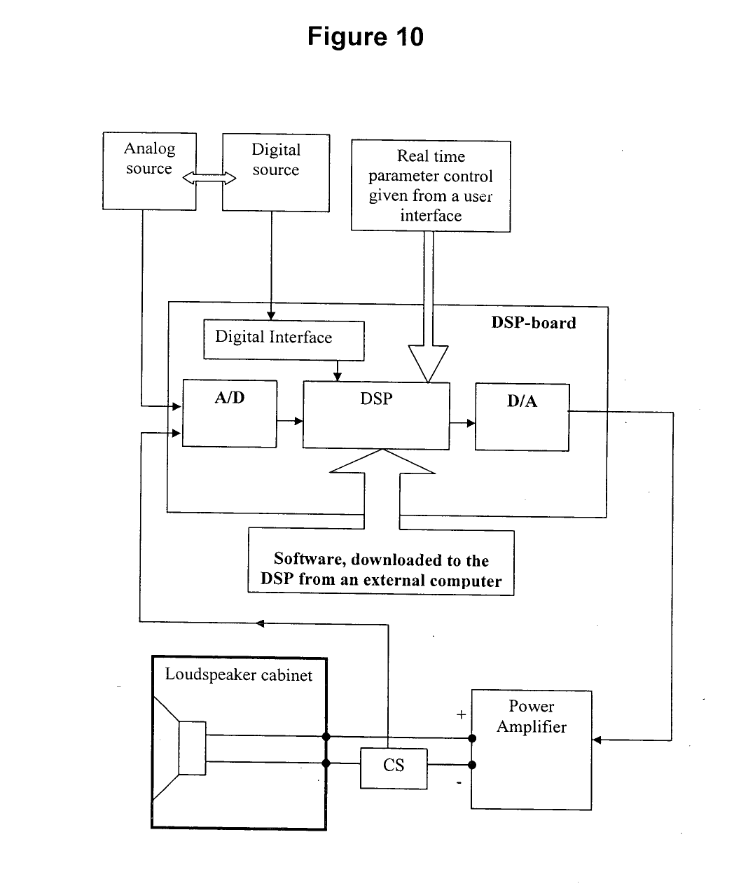

Example 1, illustrated in FIG. 10, shows how the software together with the hardware can be connected to the loudspeaker. The block Analogue/Digital Source in FIG. 10 can for example be a compact disc (CD) player or a digital versatile disc (DVD) player. The DSP-board is the host for the digital signal processor (DSP). The DSP-board is also equipped with low latency A/D and D/A converters. The DSP can be stand alone or hosted in a personal computer or integrated in a modern power amplifier.

The output from the D/A converter is then fed to a power amplifier. The output from the power amplifier is further on connected to the loudspeaker in serial with the Current Sensor (CS). The output from the CS is fed to the input of the A/D converter on the DSP-board.

The current sensor (CS) can be made from a current sensing resistance which resistance is much smaller than the loudspeaker impedance. A difference amplifier is then connected to both sides of the current sensing resistance, which all together constitutes the current censor CS. The gain of the difference amplifier is adjusted in a way that the output level is suitable for the A/D converter of the DSP-board.

### Example 2

Example 2 describes a setup for the filter G, filter F and the constant k illustrated in FIG. 4. The equivalent output impedance Fk-G of the electrical network, illustrated in FIG. 5, is chosen in such a way that the resistive part of the impedance in general has negative values and moves toward zero for higher frequencies. More precisely that is done by choosing F (FIG. 4) to be a second order band-pass filter, choosing the constant k to be positive, and choosing G to be a low-pass filter with a cutoff frequency above the center frequency of filter F.

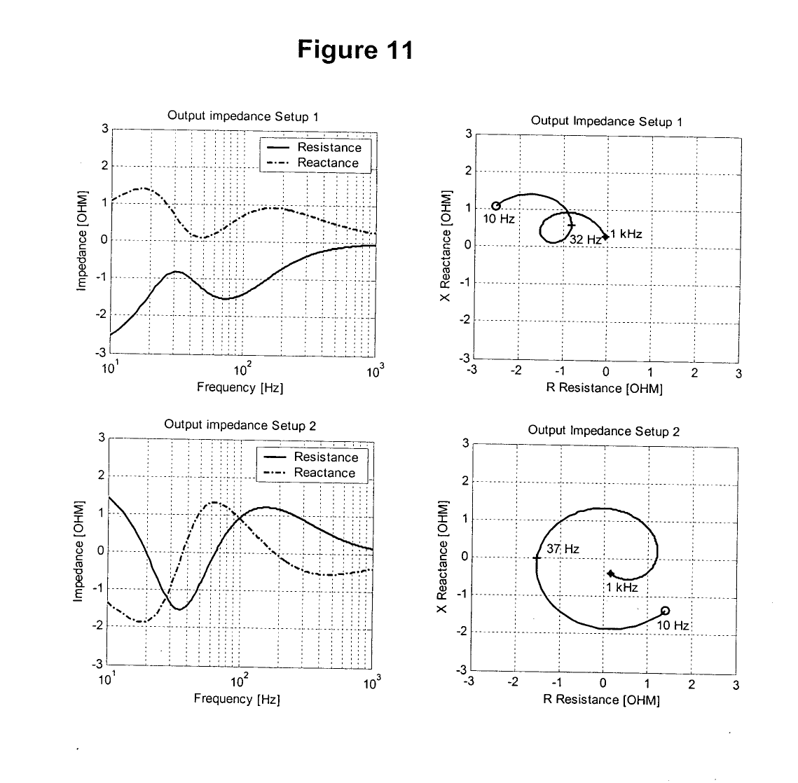

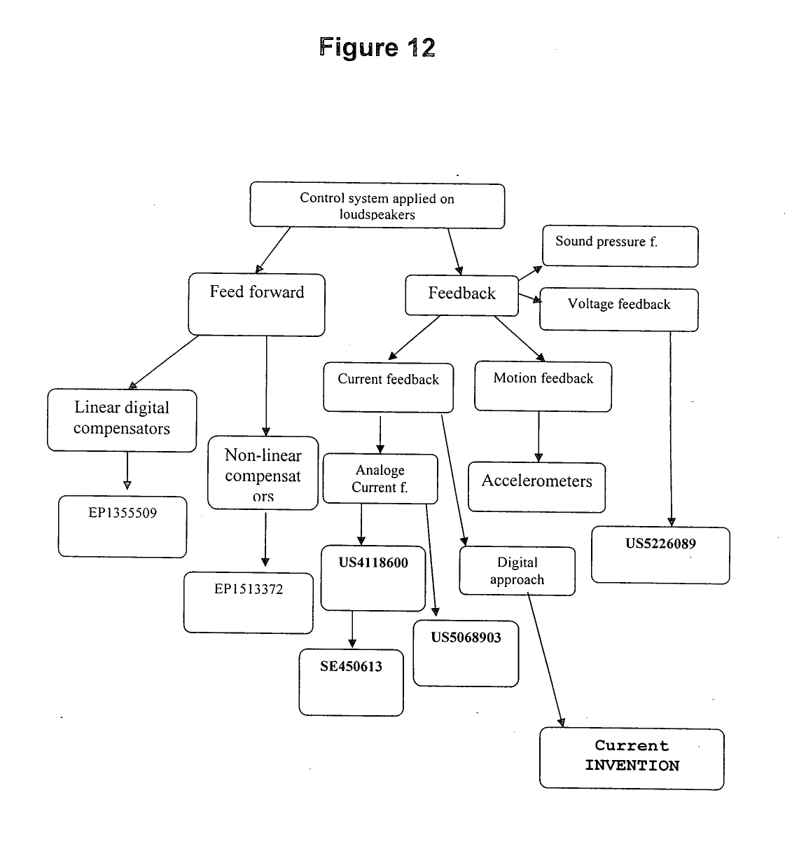

A simulation of the output impedance of such a setup is illustrated in “Setup 1” in FIG. 11. The graphs to the left in FIG. 11 show the output resistance and the output reactance as a function of frequency. The graphs to the right in FIG. 11 shows Nyquist plots of the output impedance, with the resistive part on the X-axis and the reactive part on the Y-axis.

“Setup 1”, illustrated in the two upper plots in FIG. 11, shows the output impedance of such a system. The negative resistance has a local minimum around the center frequency of the band-pass filter, and the total impedance is decreasing to zero for high frequencies. The setup will typically decrease the harmonic distortion for low frequencies where the non-linear compliance is the dominating source for distortion, but add some second tone distortion for higher frequencies where the electrical side in the voice-coil in the electrodynamic driver is the dominating source for distortion.

### Example 3

Example 3 describes a setup for the filter G, filter F and the constant k illustrated in FIG. 9. The equivalent output impedance Fk-G of the electrical network, illustrated in FIG. 5, is chosen in such a way that the resistive part of the impedance changes sign from positive to negative values, then from negative to positive values and thereafter moves toward zero for higher frequencies. More precisely that is done by choosing F (FIG. 9) to be a second order band-pass filter, choosing the constant k to be negative and choosing G (FIG. 9) to be a low-pass filter with a cutoff frequency above the center frequency of filter F and applying a negative sign to the filter G.

A simulation of such a setup with that output resistance and output reactance is illustrated in “Setup 2” in FIG. 11. The graphs to the left in FIG. 11 show the output resistance and the output reactance as a function of frequency. The graphs to the right in FIG. 11 shows Nyquist plots of the output impedance, with the resistive part on the X-axis and the reactive part on the Y-axis.

“Setup 2”, illustrated in the two lower plots in FIG. 11, shows the output impedance of such a system, where both the output resistance and reactance passes zero twice, which can bee seen in both the left and the right plot.

Block GP, illustrated in FIG. 9 is finally used to equalize the frequency response to the desired target frequency response of the system. The filter coefficients are calculated from simulations of the system or from acoustical measurements of the apparatus connected to the actual loudspeaker.

The setup will typically decrease the harmonic distortion for low frequencies where the non-linear compliance is the dominating source for distortion with help of negative output impedance, and also reduce distortion for higher frequencies where the electrical side in the voice-coil in the electrodynamic driver is the dominating source for distortion with help of positive output impedance.

### Example 4

Example 4 describes a setup method for the filters F and G and block GP illustrated in FIG. 9. Measurements are performed of the harmonic distortion of the loudspeaker connected to the apparatus illustrated in FIG. 10 which is programmed with software so it has the functionality illustrated in FIG. 9. During a tuning process, different feedback settings for each frequency are tested, meaning: Testing different magnitude and phase-angles for the current feedback loop for each frequency and measuring the resulting distortion at a constant sound pressure level. For each frequency a feedback setup is stored so it meats the wanted design target. A map as a function of frequency over the feedback system is thereby created as a result.

The map is thereafter transformed into filter coefficients for filter G and F (FIG. 9) in such a way that the electrical output impedance of the apparatus approximately corresponds to the map. One example to find the solution to the coefficients for G and F is to set the constant k to zero, the transfer function of filter F to one, and create a Finite Impulse Response (FIR) or an Infinite Impulse Response (IIR) filter for the block G which transfer function approximately is equivalent with the map. The acoustical response of the system is thereafter measured and an equalizer is calculated to equalize the system to the desired target response. The equalizer is then transformed to the filter GP.

An observer is finally connected to the system that tracks the electrical impedance of the loudspeaker. That is done by software in the DSP-processor that is observing the output signal from the DSP, which is directly proportional to the voltage fed to the loudspeaker, and the current input signal, which is directly proportional to the current flowing through the loudspeaker. Based on theses two signals the electrical impedance is calculated by the DSP processor, by calculating the quotient between the voltage signal and the current signal for an example in the frequency domain based on blocks of data.

The observer then modifies the filter G in FIG. 9 and compensates for changes for an example caused by different voice coil temperatures in such a way that the total impedance of the apparatus connected to the loudspeaker is approximately held constant over time.

### Example 5

Example 5 describes examples on features for the user of the invention.

The apparatus described in Example 1, is equipped with a user interface in such a way that the user of the apparatus can choose different output impedances and equalizer setups. For an example the user interface can provide the user with the possibility to choose between the setup described in example 2, the setup described in example 3 and the setup described in example 4, generating the possibility to chose what type of distortion pattern for low frequencies that the user prefers, when music is played on the loudspeaker. Also the apparatus can have a database of presets, matching different loudspeakers that the user can choose between.

While the invention has been described with reference to specific embodiments, it will be appreciated that numerous variations, modifications, and embodiments are possible, and accordingly, all such variations, modifications, and embodiments are to be regarded as being within the spirit and scope of the invention.

What is claimed is:

1. An apparatus for affecting the bass response and harmonic distortion of an electrodynamic loudspeaker by affecting the electrical signal fed to the voice coil of said loudspeaker, comprising: means including an electrical network based on current feedback from a current sensor in series with said loudspeaker, adding an effective output impedance that substantially is greater than zero for low frequencies, and consisting of both positive and negative resistance.

2. The apparatus in accordance with claim 1, wherein the output impedance consist of both positive and negative reactance.

3. The apparatus in accordance with claim 1, wherein the output impedance consist of positive or negative reactance.

4. The apparatus in accordance with claim 1, which is fed with a source signal that is processed with an equalizer or a crossover network.

5. The apparatus in accordance with claim 1, further comprising an equalizer for room correction.

6. An apparatus for affecting the bass response and harmonic distortion of an electrodynamic loudspeaker by adding an effective output impedance to a power amplifier, comprising a signal processor fed with input signal and current feedback signal from a current sensor, wherein the signal processor generates an output signal fed to said power amplifier which output impedance appears substantially greater than zero for low frequencies and wherein the time-delay from said current feedback signal to the output signal is substantially less than the period time of the upper frequency limit of the affected bass response frequencies.

7. The apparatus in accordance with claim 6, having analogue to digital converters connected to input from said signal processor and digital to analogue converters connected to the output of the signal processor, wherein said current sensor measures the voltage over a resistor that is connected in serial with the loudspeaker, and wherein the resistance of the resistor is significantly lesser than the voice coil resistance.

8. The apparatus in accordance with claim 7 where said analogue to digital converters and digital to analogue converts are equipped with anti-aliasing filters which are of a minimum-phase type.

9. The apparatus in accordance with claim 6, wherein said effective output impedance consists of both positive and negative resistance.

10. The apparatus in accordance with claim 6 wherein the electrical loudspeaker impedance is observed over time by the signal processor, and wherein the output impedance is adjusted thereafter.

11. The apparatus in accordance with claim 7, further comprising a user interface giving one or more possibilities to adjust the output impedance of the apparatus to affect the bass response.

12. The apparatus in accordance with claim 6, further comprising one or more settings of said output impedance and an equalizer adapted to one or several different loudspeakers.

13. The apparatus in accordance with claim 1, wherein the electrical equivalent of the output impedance is a positive resistance in series with a parallel resonance circuit having a resistive part, capacitive part and inductive part, wherein all parts have negative values and wherein the negative resistive part has a greater magnitude than the magnitude of the positive resistance.

14. The apparatus in accordance with claim 6, wherein said effective output impedance is a positive resistance in series with a parallel resonance circuit having a resistive part, capacitive part and inductive part, wherein all parts have negative values wherein the negative resistive part has a greater magnitude than the magnitude of the positive resistance.

15. A digital control system for improving the sound reproduction of an electro-dynamic loudspeaker, comprising a current sensor in series with the loudspeaker, wherein the digital control system is fed with a digital stream of data and with a time continuous signal from a current sensor, which signal is converted by converters from analog to digital.

16. The digital control system in accordance with claim 15, wherein the converters have a small latency from input to output.

17. The digital control system in accordance with claim 15, wherein the control system comprises digital implemented filters

18. The digital control system in accordance with claim 15, wherein the control system further comprises a high pass filter branch

19. The digital control system in accordance with claim 15, which is fed with a source signal that is processed with an equalizer or a crossover network.

20. The digital control system in accordance with claim 15, further comprising an equalizer for room correction.

21. The digital control system in accordance with claim 17, further comprising a user interface for changing parameters of said digital filters
